(19) United States
(12) Patent Application Publication
(10) Pub. No.: US 2007/0285178 A1
(43) Pub. Date: Dec. 13, 2007

(54) PHASE LOCKED LOOP FOR THE GENERATION OF A PLURALITY OF OUTPUT SIGNALS

(75) Inventor: Heinz Werker, Huglfing (DE)

Correspondence Address: PEARNE & GORDON LLP, 1801 EAST 9TH STREET, SUITE 1200, CLEVELAND, OH, 44114-3108, US

(73) Assignee: NATIONAL SEMICONDUCTOR GERMANY AG, Unterhaching (DE)

(21) Appl. No.: 11/751,905

(22) Filed: May 22, 2007

(30) Foreign Application Priority Data
May 24, 2006 (DE) 10 2006 024 469.9

(51) Int. Cl. H03L 7/00

(52) U.S. Cl. 331/16

(57) ABSTRACT

The invention concerns a phase locked loop or “PLL” (12) as well as a method for the operation of a PLL, in which a controllable oscillator (DCO) generates an output signal (CKout) of the phase locked loop, and a phase detector (PD) determines a phase difference between a clock signal (CKin) used as an input clock signal of the PLL (12), and the PLL output signal (CKout), and provides a phase detector output signal (PD_OUT) synchronising the oscillator (DCO) with the clock signal (CKin) used. Here, in order to be able to provide a plurality of PLL output signals with an adjustable relative phase difference that are synchronised with the clock signal (CKin) provision is made according to the invention that for the determination of the phase difference an adjusted phase-shifted version (CK<1:8>) of the output signal (CKout) of the PLL is generated and compared with the phase of the clock signal being used (CKin), and that the adjusted phase-shifted version (CK<1:8>) of the PLL output signal (CKout) is provided as a further PLL output signal (CK<1>).

### BACKGROUND OF THE INVENTION

1. Field of the Invention

The present invention concerns a phase locked loop with a controllable oscillator for the generation of an output signal of the phase locked loop, and with a phase detector to determine a phase difference between a clock signal used as an input clock signal of the phase locked loop, and the output signal of the phase locked loop, and for the provision of a phase detector output signal synchronising the oscillator with the clock signal used.

Further, the invention concerns a method for the operation of a phase locked loop, in which with a controllable oscillator an output signal of the phase locked loop is generated, and with a phase detector a phase difference is determined between a clock signal used as an input clock signal of the phase locked loop, and the output signal of the phase locked loop, and a phase detector output signal is provided synchronising the oscillator (DCO) with the clock signal used.

2. Description of the Prior Art

A phase locked loop of this kind, in what follows also abbreviated to “PLL”, and an operating method for a PLL, are of known art, for example, from U.S. Pat. No. 6,741,109.

In general terms a PLL serves the purpose of synchronising a controllable oscillator, which generates an output signal with an output frequency, with an input clock signal with an input frequency, by means of feedback. For this purpose the PLL comprises a phase detector or phase comparator, at whose input the input clock signal and the PLL output signal are present. A signal representing the phase difference between these two signals is mainly used to control the oscillator via an active or passive, digital or analogue filter (“loop filter”).

The areas of application for PLL circuits are many and varied. For example PLLs can be used for clock signal recovery from digital signal sequences, or for FM demodulation. In communication standards such as “SONET” or “SDH” clock generation circuits are required to generate clock signals during the transmission and receipt of data. In a circuit of this kind a PLL circuit can generate, e.g. from an input clock signal inputted as a reference, one or a plurality of output clock signals for use in a communication system. Here the synchronisation of the PLL output signal with an input clock signal does not necessarily mean that the frequencies of these two signals are identical. Rather, in a manner known per se, a more or less arbitrary frequency relationship can be implemented by an arrangement of frequency dividers at the input and/or at the output and/or in the feedback path of the PLL circuit.

The above-mentioned U.S. Pat. No. 6,741,109 assumes that with a PLL of this kind a switch can be made between a first clock signal and a second clock signal to be used as an input clock signal of the PLL. This in no way excludes the possibility that more than two clock signals can be used as an input clock signal of the PLL. Rather it is essential that from a plurality of clock signals it is always just one clock signal that is selected and actually used to generate the PLL output signal. The provision of a plurality of clock signals can, in particular, be advantageous in the creation of redundancy in a communication system. If, for example, one of the clock signals serving as a reference “goes missing” then in the PLL circuit of the clock generation circuit a switch can take place to another clock signal to be used as an input clock signal of the PLL. In particular when the PLL is applied in communication systems for clock signal extraction or recovery it is desirable that no significant phase alteration (“phase hit”) occurs in the PLL output signal as a result of such a switching procedure. A phase alteration of this kind can, however, occur if the first and second clock signals possess different phases immediately before the switch.

An option of known art for the avoidance of erratic alterations in phase as a result of a switching procedure consists in selecting the PLL bandwidth (“loop gain”) to be very small (for the above-mentioned communication systems, for example, of the order of a few Hz). In this case the phase of the PLL output signal alters only very slowly, even if the clock signals between which the switch is made have a comparatively large phase difference immediately before the switch. In the communication systems cited no data transfer errors then occur. However, this solution possesses in particular the following two disadvantages: On the one hand a particularly small PLL bandwidth is difficult to achieve in an integrated circuit arrangement. On the other hand a particularly small PLL bandwidth also results in a disadvantageously smaller capture range for the PLL. For a PLL bandwidth of a few Hz the PLL capture range can, for example, be less than 1 ppm.

In the above-mentioned U.S. Pat. No. 6,741,109 it is recommended for the avoidance of phase alterations of the phase output signal as a result of a switching procedure, i.e. to guarantee “hitless switching”, that for the clock signal that is currently not being used to generate the output signal the phase difference with reference to a feedback signal derived from the PLL output signal is determined and stored. If a switch to this clock signal takes place then the stored phase difference is injected at a suitable point into the PLL to compensate for the phase difference. What is problematic in this solution is the accuracy of the compensation that can be achieved in practice, and the complexity of the circuitry required for the compensation.

Independently of the above, utilisation of the PLL output signal to generate a plurality of output clock signals is provided in an application example described in the above-mentioned U.S. Pat. No. 6,741,109 (in FIG. 15 of this document). These output clock signals are suitable for use in a communication system (in accordance with SONET or SDH standards), and are generated by the supply of the PLL output signal to an appropriate number of output dividers (frequency dividers).

What is disadvantageous in the PLL of known art, that is to say, in the PLL circuit formed with the PLL, is that the relative phase difference between different output clock signals is fixed by the characteristics of the output dividers and cannot be varied. In many applications, on the other hand, the desire exists to be able to adjust a relative phase difference of a plurality of output clock signals, i.e. to adjust a “phase offset” for individual output clock signals. In general terms the provision of additional adjustable delay elements comes into consideration for the adjustment of a phase offset for an output signal. As a rule, however, such an approach leads to deterioration in the signal quality. Moreover delay arrangements of this kind normally possess high current consumption and in monolithic circuits also require a lot of space.

### SUMMARY OF THE INVENTION

It is an object of the present invention to improve a phase locked loop and/or a method of the kind cited above to the effect that therewith a plurality of output clock signals synchronised with an input clock signal can be provided with an adjustable relative phase difference.

The phase locked loop according to the invention is characterised in that the phase detector has an adjustable phase shifting device to generate an adjusted phase-shifted version of the output signal of the phase locked loop, and has a phase comparison device generating the phase detector output signal to determine the phase difference between the clock signal being used and the adjusted phase-shifted version of the output signal, and in that the adjusted phase-shifted version of the output signal is provided as a further output signal of the phase locked loop.

The operating method according to the invention is characterised in that in the determination of the phase difference an adjusted phase-shifted version of the output signal of the phase locked loop is generated and compared with the phase of the clock signal being used, and in that the adjusted phase-shifted version of the output signal is provided as a further output signal of the phase locked loop.

With the invention a “further output signal” of the phase locked loop is provided in a simple manner in terms of circuitry, which signal firstly is synchronised with the clock signal being used as a PLL input clock signal, and secondly possesses an adjustable phase difference with reference to the “standard PLL output signal”.

For use in a communication system, for example, a phase locked loop circuit can be implemented with the invention, which comprises such a phase locked loop and an output switching device connected with a plurality of circuit outputs, to which the PLL output signal and the further PLL output signal are supplied, and which in each case forwards either the “output signal” or the “further output signal” to the plurality of circuit outputs. Here the circuit outputs can e.g. be formed from output dividers of a conventional kind.

In a preferred form of embodiment provision is made that the PLL output signal is provided with a plurality of phases, and the phase-shifted version of the output signal is generated by an adjustable interpolation between these phases. In the PLL according to the invention this can e.g. be implemented in that the oscillator is designed such that the output signal is to be provided to the phase detector with a plurality of phases, and the adjustable phase shifting device is designed as an adjustable phase interpolator to interpolate between these phases and to provide an adjusted interpolated signal.

In one form of embodiment the phase detector comprises:
an adjustable phase interpolator to interpolate between a plurality of phases of the PLL output signal, and to provide an adjusted interpolated signal, and
a phase comparison device to compare the phase of the clock signal with the phase of the interpolated signal, and to provide a phase detector output signal representing the phase difference.

If the interpolated signal is provided with a plurality of phases then one of these phases can be provided as the further output signal of the phase locked loop.

In one form of embodiment provision is made that the phase detector output signal is a digital representation of the phase difference determined. In this case the phase detector output signal can be entered into a digital filter, which delivers a control signal for a digitally controlled oscillator, or DCO. Needless to say an analogue voltage controlled oscillator, or VCO, can also be used by means of appropriate modifications in the region of the PLL filter.

In the invention the ability to switch, known per se, can advantageously be provided between a plurality of clock signals available for use as an input clock signal of the phase locked loop, be it with or without measures for “phase matching during switching” (i.e. for “hitless switching”). As can be seen in particular from the example of embodiment described further below, components of the phase locked loop can here be used advantageously in totally different respects, that is to say, can be used severalfold. In one form of embodiment the phase locked loop comprises a switching device to switch between a first clock signal and a second clock signal to be used as an input clock signal of the phase locked loop, wherein a separate phase detector connected with the switching device is provided for each of the two signals.

In a further development of such a switchable phase locked loop provision is made that each of the phase detectors can be switched between a first operating mode for the clock signal currently being used and a second operating mode for the clock signal not currently being used, and wherein the phase shifting device of the phase detector currently in the second operating mode is adjusted to avoid a jump in phase during the switch. In this case the phase displacement device is used in the first operating mode of the phase detector concerned for the actual PLL control and provision of the “further PLL output signal”, whereas the same phase shifting device in the second operating mode of the phase detector is used for phase matching in the sense of “hitless switching”.

In a further development of the phase locked loop provision is made that each phase detector contains a phase locked loop activated in the second operating mode, which loop controls the phase detector output signal representing the phase difference such that this phase detector output signal is used to adjust the phase shifting device.

In a form of development provision is made that for the clock signal currently not being used for the generation of the PLL output signal the adjustment of the phase shift is executed by a phase control function, in which a signal representing the phase difference is controlled such that the signal is used for an adjustment of the phase shift of the PLL output signal. The phase shifting device used for this purpose can take the form of e.g. the above-mentioned phase interpolator.

In a form of embodiment it is envisaged that for each of the two clock signals a phase detector is provided that can be switched between different operating modes, wherein the phase detector for the clock signal currently being used is put into a first operating mode and a phase detector for the clock signal currently not being used is put into a second operating mode, and wherein each phase detector in the first operating mode determines a phase difference between the clock signal being used and an adjusted phase-shifted version of the output signal, and provides this phase difference for the control of the oscillator, and in the second operating mode adjusts the phase shift. Here for the clock signal currently being used to generate the output signal a phase difference is thus determined between this clock signal and an adjusted phase-shifted version of the output signal, and is used for the control of the oscillator, whereas for the clock signal currently not being used to generate the output signal the adjustment of the phase shift is carried out.

In the above-mentioned further development any phase difference present between a plurality of clock signals that can be used as an input clock signal is effectively already adapted or compensated before the switch, in particular so that any undesired alteration in phase of the PLL output signal as a result of the switch can be avoided with high precision (“hitless switching”).

### BRIEF DESCRIPTION OF THE DRAWINGS

In what follows the invention is further described with the aid of an example of embodiment with reference to the accompanying drawings. In the figures:

FIG. 1 shows a PLL circuit,

FIG. 2 shows the structure of the phase detectors used in the PLL circuit of FIG. 1,

FIG. 3 shows the structure of a sampling device used in the phase detector of FIG. 2,

FIG. 4 shows the structure of a multiphase sampler used in the sampling device of FIG. 3,

FIG. 5 shows an exemplary representation of the time profiles of signals that occur at the multiphase sampler of FIG. 4,

FIG. 6 shows the structure of a phase interpolator used in the phase detector of FIG. 2, and

FIG. 7 shows the structure of two interpolator halves used in the phase interpolator of FIG. 6.

### DESCRIPTION OF THE PREFERRED EMBODIMENT(S)

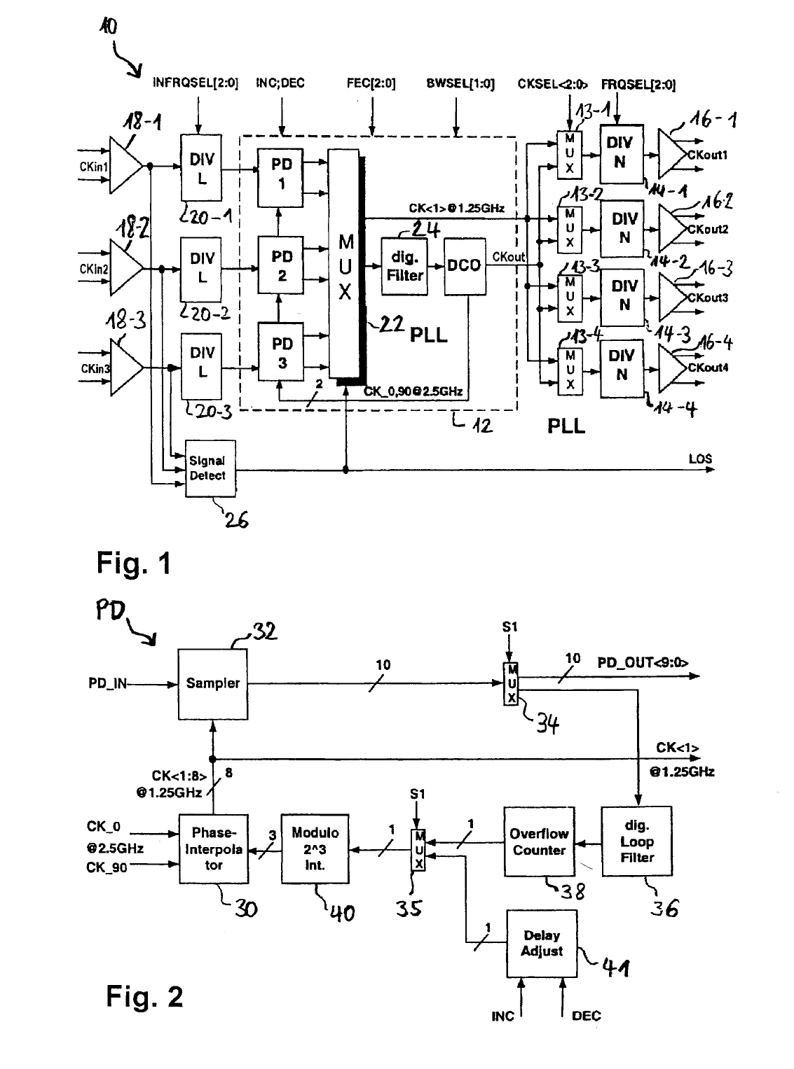

FIG. 1 shows a PLL circuit 10 with a PLL (phase locked loop) 12.

The PLL 12 has a digital controllable oscillator DCO for the generation of an output signal CKout, or a two-phase version of this output signal with two phases CK_0 and CK_90. The two signals CK_0, CK_90 possess a fixed phase difference of 90° relative to each other, and fixed phase differences relative to the output signal CKout. In the simplest case the signal CKout is identical with one of the signals CK_0 or CK 90.

In the example of embodiment represented the PLL output signal CKout can be fed to a plurality of output dividers 14-1 to 14-4, each of which subjects the PLL output signal to a frequency division with a prescribed division ratio, and outputs to output stages 16-1 to 16-4, each of which converts the signal into a differential output clock signal CKout1 to CKout4. The PLL output signal CKout is not directly applied to the four output divider-output stage arrangements, but via an output switching device designed as a multiplex device consisting of a plurality of output switches 13-1 to 13-4. By means of these output switches 13-1 to 13-4 either the PLL output signal CKout or a “further PLL output signal” CK<1>, described further below, is supplied in each case to each of the output dividers 14-1 to 14-4.

On the input side a plurality of differential clock signals CKin1 to CKin3 is supplied to the circuit 10, each of these signals being firstly converted into a non-differential representation by means of three input stages 18-1 to 18-3, and inputted via three input dividers 20-1 to 20-3 to the PLL 12.

For each of the clock signals CKin1 to CKin3, in what follows also designated as “input signal CKin” a phase detector PD1, PD2 or PD3 is respectively provided, as represented.

Each of these phase detectors PD1 to PD3, in what follows also designated as “phase detector PD”, in a certain operating mode (the “first operating mode”) is able to determine a phase difference between the clock signal CKin concerned (or the frequency-divided version of the clock signal produced by the divider 20-1, 20-2 or 20-3 respectively) and an adjusted phase-displaced version of the output signal CKout, and is able to provide this phase difference for the control of the digitally controlled oscillator DCO. To this end the outputs of the phase detectors PD are connected with a multiplexer or switching device 22, the latter being designed to select one of the three signals outputted from the phase detectors PD1 to PD3, and to output it to a PLL filter 24 (phase detector output signal PD_OUT). In the example of embodiment represented each phase detector PD in its first operating mode generates a phase detector output signal (PD OUT<9:0> in FIG. 2) representing this phase difference digitally, which signal is filtered by the PLL filter 24, in this example of embodiment of digital design, and outputted to a control input of the oscillator DCO. The frequency of the PLL output signal CKout outputted by the DCO is controlled by the signal outputted from the PLL filter 24.

By means of the switching device 22 it is thus possible to switch between the three clock signals CKin1 to CKin3 to be used as an input clock signal of the PLL. Each such switch is initiated by a signal detection device 26, to which the clock signals CKin1 to CKin3 are applied on the input side, as represented, and on the output side is connected with the switching device 22. The device 26 detects the quality of the clock signals CKin and on the basis of this detection makes a decision as to which of the clock signals should be used as the PLL input clock signal, or to which other input clock signal a switch should be made, if the currently used clock signal becomes unserviceable. By means of a signal LOS the latter circumstance is also communicated to other sections (not represented) of an integrated circuit arrangement, which also comprises the PLL circuit 10 represented.

Simultaneously with the switch between different phase detector output signals PD_OUT to be used as an input signal of the digital filter 24, the switch also takes place by means of the switching device 22 between “further phase detector output signals” CK<1>, which are outputted by the respective phase detectors PD1 to PD3 in the first operating mode (phase detector used for PLL control) and also in a “second operating mode”, described further in what follows (phase detector not used for PLL control). If, for example, the clock signal CKin1 is currently being used as an input signal to the PLL 12, then PD1 is in the first operating mode, whereas PD2 and PD3 are in the second operating mode. The phase detector output signal PD_OUT<9:0> and the further phase detector output signal CK<1> of the phase detector PD1 are forwarded via the switching device 22 to the PLL filter 24, and hence to the output switching devices 13-1, 13-2, 13-3, 13-4. The corresponding output signals of the phase detectors PD2 and PD3 are not forwarded.

FIG. 2 illustrates the (identical) structures of the three phase detectors PD1, PD2 and PD3. Because of the identical structure of the three phase detectors this structure is described for just one detector PD with reference to FIG. 2. All components and signals described in what follows for the phase detector PD are correspondingly and separately present in each of the phase detectors PD1 to PD3 in the circuit 10 represented in FIG. 1.

The essential components for the first operating mode, already mentioned above, of the phase detector PD are an adjustable phase interpolator 30 and a sampling device 32. The two “quadrature signals” CK_0, CK_90 of the PLL output signal CKout are inputted to the phase interpolator 30. Corresponding to an interpolation adjustment described further below, the interpolator 30 generates an adjusted interpolated signal CK<1:8>, which is supplied as an input signal to the sampling device 32. In the example of embodiment represented the phase interpolator 30 interpolates between the two sinusoidal quadrature clock signals CK_0, CK_90 of the DCO, which oscillates at a frequency of 2.5 GHz. The signal representation CK<1:8> consists of eight signal components and represents a “phase-shifted version of the PLL output signal” CKout (according to the interpolation adjustment). The sampling device 32 possesses the function of a phase comparator and compares the phase-shifted version CK<1:8> of the output signal CKout (fed as quadrature signal components CK_0 and CK_90 to the phase detector PD) with the phase of a phase detector input signal PD_IN. As a result of this comparison the sampling device 32 outputs a digital signal representation PD_OUT<9:0>, which in the first operating mode of the phase detector PD is fed via a first phase detector switching device 34 to the phase detector output, which is connected with the PLL switching device 22 (FIG. 1). The phase detector input signal PD_IN represented in FIG. 2 is one of the signals that are outputted from the input dividers 20-1 to 20-3 represented in FIG. 1.

Returning once again to FIG. 1, in what follows it is e.g. assumed that, initiated by the signal detection device 26 and implemented by the PLL switching device 22, the clock signal CKin1 is currently being used as an input clock signal of the PLL 12, and that at a later point in time a switch to the clock signal CKin2 should take place. In this situation the phase detector PD1 is in its first operating mode, which has already been elucidated above with reference to FIG. 2. The two other phase detectors PD2 and PD3 are, however, in the second operating mode, described in what follows once again with reference to FIG. 2, in which these detectors do not provide any input clock signal for the PLL.

The switch of the phase detector represented in FIG. 2 from its first operating mode into its second operating mode is effected by a signal SI, outputted from the signal detection device 26 or the PLL switching device 22, which signal controls the first phase detector switching device 34 such that the phase detector output signal PD_OUT<9:0> outputted from the sampling device 32 is no longer outputted as a reference clock to the PLL, but acts back onto the phase interpolator 30 via a feedback path provided in the phase detector PD. In the example of embodiment represented this feedback path is formed from a digital filter 36, an overflow counter 38 and a modulo-8 integrator 40. Between the overflow counter 38 and the modulo-8 integrator 40 is arranged a second phase detector switching device 35, which is controlled by the signal S1 in the same way as the first switching device 34, and which in the second operating mode forwards the output signal of the overflow counter 38 to the integrator 40, but in the first operating mode forwards the output signal of a delay adjusting device 41, described further below, to the integrator 40.

In the second operating mode the phase detector output signal PD_OUT<9:0> is fed via the digital filter 36 to an input of the overflow counter 38, which for each counter overflow outputs an output pulse to the modulo-8 integrator 40. On the output side the integrator 40 outputs an adjustment signal for the adjustable phase interpolator 30, for which eight different signal states are provided corresponding to eight different interpolation stages.

Because of the circumstance in which, in the second operating mode of the phase detector PD, the adjustment of the phase interpolator 30 influences the phase of the signal CK<1:8> and thus indirectly influences the phase detector output signal PD_OUT<9:0>, drawn on for the interpolation adjustment, a phase control function is carried out in the phase detector PD, in which the adjustment outputted by the integrator 40 is varied until a state is reached in which the phase detector output signal is controlled to a value that essentially correspondence to a phase difference of zero. If the phase detector PD is active and is incorporated into the PLL loop (first operating mode), then the whole feedback path 36, 38, 40 is inactive. In this first operating mode, however, in a manner described further below, the adjustment value outputted from the modulo-8 integrator 40 to the phase interpolator (which defines the phase displacement between CK_0, CK_90 und CK<1:8>) can be altered by means of the delay adjusting device 41.

This phase control is carried out in all the phase detectors PD (in the second operating mode) that are not currently being used to generate the PLL output signal. In this manner an “internal phase adjustment” is effectively created with regard to the PLL output signal for all the different clock signals CKin, before any switch occurs between the clock signals CKin defining which is to be used as a PLL input clock signal. One can effectively present the function of this internal phase control, which takes place in the second operating mode of each phase detector PD, as a “PLL within the phase detector”. With the components 38, 40, 30 the function of a digitally controllable oscillator of this “internal PLL” is provided.

If now a switch takes place in the PLL circuit 10 (FIG. 1) to a clock signal not previously used for PLL output signal generation, then for the phase detector PD concerned the internal switching device 34 is converted by the signal S1 such that the phase detector output signal PD_OUT<9:0> is supplied via the PLL switching device 22, likewise switched accordingly, to the PLL filter 24. Because of the adjustment of the phase interpolator 30, previously undertaken in a controlled manner by means of the “internal PLL”, this switch does not lead to a disadvantageous phase alteration in the phase output signal (as would be anticipated if the phase interpolator 30 had not previously been adjusted accordingly). In the example of embodiment represented “hitless switching” is thus implemented.

A further special feature of the PLL circuit 10 consists in that each of the four output signals CKout1 to CKout4 is generated either based on the “standard PLL output signal” CKout or based on the further phase detector output signal CK<1> of that phase detector PD that is currently in the first operating mode. The selection of one of these two signals as a basis for the provision of the corresponding output signal occurs by means of a selection signal CKSEL<2:0> represented in FIG. 1, which is supplied to the output switches 13-1 to 13-4.

For the functioning of the PLL circuit 10 two circumstances are essential: On the one hand the further PLL signal CK<1>and also the PLL output signal CKout are synchronised with the clock signal that is currently being used. This is because this additional signal CK<1> is extracted from the phase detector that is currently being used as one of the eight phases of the signal CK<1:8> (cf. FIG. 2) and thus, in the same way as the signal CK<1:8>, is just a phase-shifted version of the actual PLL output signal CKout. On the other hand it is essential that the phase difference between the further PLL output signal CK<1> and the actual PLL output signal CKout can be adjusted as required in a range and with a resolution prescribed by the configuration of the phase interpolator 30. This adjustment of the relative phase difference between the two output signals is executed on the phase detector PD that is currently being used for the PLL control by means of a corresponding control of the delay adjusting device 41. By the input of adjusting signals INC and DEC (cf. FIG. 2) to this adjustment device 41 the latter outputs via the second phase detector switching device 35 control pulses that increment or decrement the modulo-8 integrator 40. Thus in a simple manner it is possible during the PLL operation to adjust a desired phase difference between the output signals CKout and CK<1>. The adjustment occurs by means of a corresponding supply of signals INC or DEC to that delay adjusting device 41 that relates to the phase detector PD currently being used (in the first operating mode).

In other words, after the switch of the phase detector PD concerned to be used in the PLL loop, the integrator 40 and the phase interpolator 30 (in general terms the “phase shifting device”) are no longer required as components in the feedback path of the “internal PLL” for phase matching (for “hitless switching”), and are instead used for the relative phase adjustment of the output clock signals, in that, controlled via the output switches 13-1 to 13-4, with the DCO output signal applied to at least one of the output arrangements 14, 16, and the additional signal CK<1> extracted from the phase detector PD applied to at least another of the output arrangements 14, 16, the relative phasing or phase offset between these two output signals can be adjusted according to the measure of the resolution of the phase interpolator to any required value. In the example of embodiment described this (time-wise) resolution amounts to 50 ps.

The delay adjusting device 41 delivers at the output a signal of +/−1, dependent on the input signals INC or DEC. If, for example, 4 pulses of the INC signal are detected, then the delay adjusting device delivers 4 times a value of +1 to the modulo-8 Integrator 40, which leads to a phase displacement of 4×50 ps=200 ps for the sampling clock signal components CK<1:8>. On the basis of this phase displacement of 200 ps the sampling device 32 alters the digital output value by a value of 2. The oscillator DCO alters the output phase by 200 ps, this, however, with the time constant of the PLL bandwidth. Each output clock signal of the circuit arrangement that is generated on the basis of the DCO output is then likewise displaced in its phase by 200 ps. For an output clock signal, which in contrast is extracted from the phase detector output CK<1>, the phase alteration will take place immediately after each INC or DEC pulse, wherein this phase alteration however is again corrected with the time constant of the PLL bandwidth, so that at the end the clock signals connected with the oscillator DCO and the phase detector output CK<1> possess a mutual phase offset of 200 ps.

In summary, with the described PLL circuit 10 a switch can be made between a plurality of clock signals to be used as an input clock signal of the PLL, wherein the PLL phase detector currently used in each case compares the phase of an adjusted phase-shifted feedback signal with the phase of the input signal currently being used, and phase detectors that are not currently being used already undertake in this time period an adjustment of the phase displacement, which in the event of their utilisation as a PLL phase detector is used as an “initial adjustment”. Thus for the newly used phase detector a desired phase difference can be adjusted between the two PLL output signals. Independently of this then it can be separately determined, by means of the output switching devices (switches 13-1 to 13-4) for each of the circuit output signals CKout1 to CKout4, which of the two PLL output signals is used in the generation.

Needless to say, in a deviation from the described example of embodiment another number of clock signals at input and/or another number of output clock signals can also be provided. Moreover the number and arrangement of the frequency dividers 14, 16 can be adapted to the application in question. Finally, alternatively or additionally to the signal CK<1>, also one or a plurality of further signal components of the interpolation signal CK<1:8> could be branched off from the phase detectors and could be applied via the (then correspondingly modified) output switching device 13 in the generation of the circuit output signals. In this manner even more PLL output signals, differing in their phase from one another, could be provided.

The structure of the phase detector PD represented in FIG. 2 represents a preferred form of embodiment, but needless to say could also be implemented in another manner. However, a structure is preferred by means of which (as for the structure described) an internal phase control loop within the phase detector is implemented for the adjustment of the phase displacement in the second operating mode. As far as the phase displacement as such is concerned, the described implementation by means of a phase interpolator is likewise to be considered simply as a preferred embodiment, which could also be designed in another manner. The same applies for the detailed configuration, described further in what follows, on the one hand of the sampling device 32 and on the other hand of the phase interpolator 30, which could also be designed in another manner other than that described in what follows.

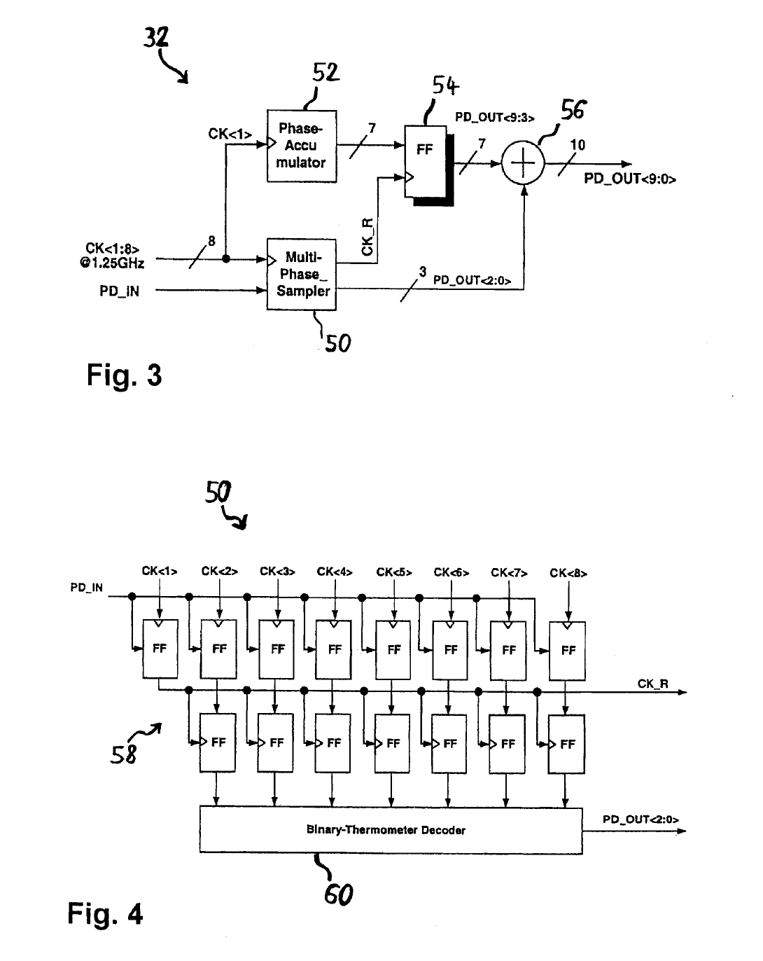

FIG. 3 shows the structure of the sampling device 32 used in the phase detector PD of FIG. 2.

The phase-shifted version CK<1:8> of the PLL output signal CKout and also the phase detector input signal PD_IN are inputted into a multiphase sampler 50, which from these generates signals CK_R and PD_OUT<2:0>. A signal component CK<1> of the signal CK<1:8>, which in total consists of eight signal components CK<1> to CK<8>, is also inputted to a phase accumulator 52 (counter) . A signal outputted from the phase accumulator 52, and also the signal CK_R are, as represented, applied to a flip-flop arrangement 54 consisting of seven flip-flops; the latter forms a signal component PD_OUT<9:3>, which fed via the summation element 56 to which the signal PD_OUT<2:0> is also applied, forms the phase detector output signal PD_OUT<9:0>. In the example of embodiment represented the sampling device 32 generates at its output a 10-bit word, which represents the phase difference of the signals supplied to the phase detector PD in a digital manner. The sampling device 32 comprises the multiphase sampler working at high speed in the provision of the signal PD_OUT<2:0>, which represents the three bits of lowest value of the phase detector output signal. The flip-flop arrangement 54 generates the seven highest value bits. The multiphase sampler samples the supplied phase detector input signal PD_IN, which in the example represented has a frequency of 19.44 MHz, with the 8 evenly spaced clock signals CK<1> to CK<8>, which in the example of embodiment represented possess a frequency of 1.25 GHz and supply a phase resolution of 100 ps.

FIG. 4 shows the structure of the multiphase sampler 50 represented in FIG. 3. The multiphase sampler 50 contains as represented a flip-flop arrangement 58 and also a decoder 60, to which the signals PD_IN and CK<1> to CK<8> are applied in the manner represented, and on the output side outputs the signals CK_R and PD_OUT<2:0>.

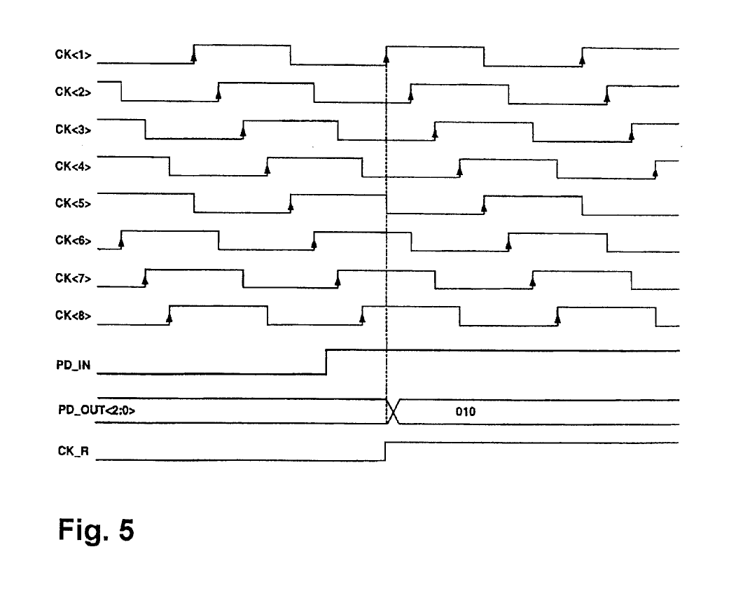

FIG. 5 shows exemplary time profiles of the signal components CK<1> to CK<8>, the signal PD_IN, the signal PD_OUT<2:0> and the signal CK_R. FIG. 5 shows in particular the phase relationship between the 8 sampling clock signals CK<1:8> and the phase detector input signal PD_IN and the phase detector output signal PD_OUT.

From this it can be seen that the signal components CK<1> to CK<8> generated from the phase interpolator 30 are identical signals that are however equidistantly displaced in phase from one another. In the example of embodiment represented the time-wise displacement between two of these signal components that are adjacent (e.g. between CK<1> and CK<2>) corresponds to 100 ps.

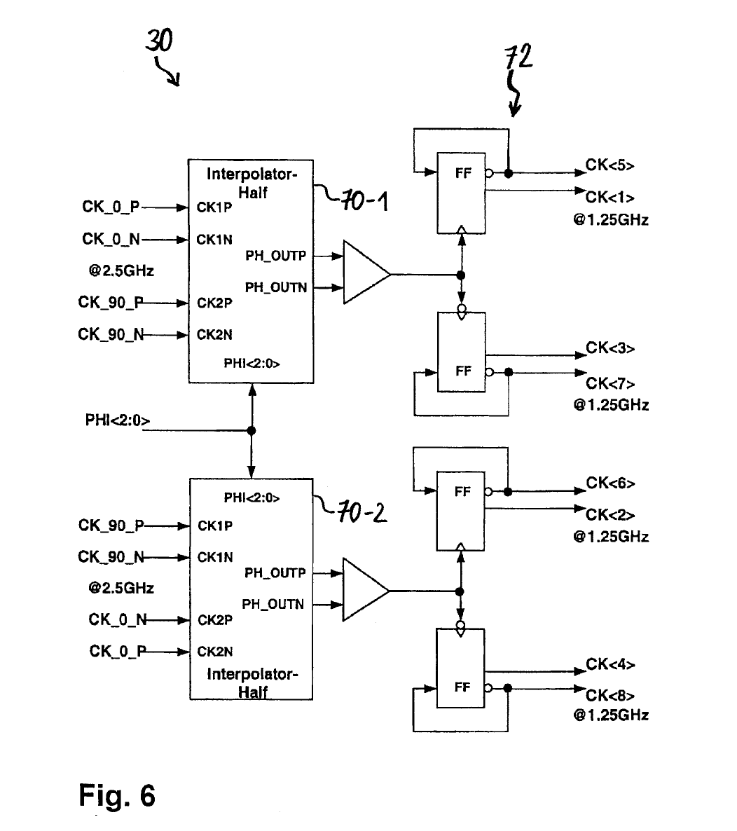

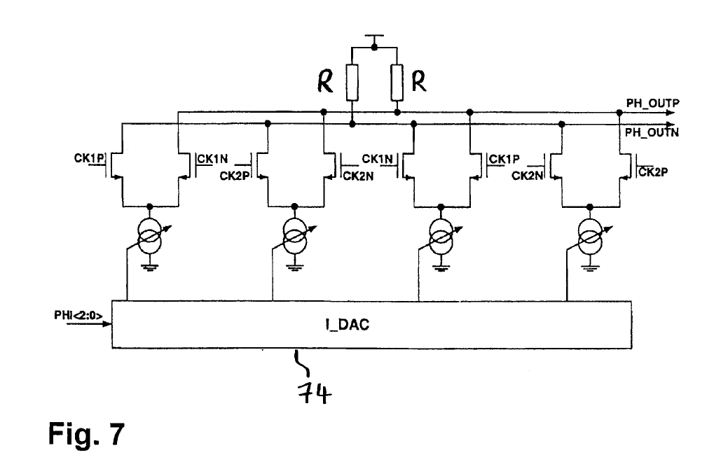

FIGS. 6 and 7 clarify the structure of the phase interpolator 30.

The overall structure of the interpolator 30 is shown in FIG. 6. In order to provide the eight evenly spaced (by 100 ps) clock signals CK<1> to CK<8> at a frequency of 1.25 GHz, the interpolator 30 comprises the two represented interpolator halves 70-1 and 70-2, and an output section of the circuit 72 with additional divider circuits. The interpolator halves 70-1, 70-2 and the interpolator output section of the circuit 72 act together in the manner represented to form from the quadrature signals CK_0 and CK_90 (cf. FIG. 1) the phase-shifted version of the PLL output signal, represented by the signal components CK<1>to CK<8>.

The quadrature signals CK_0 and CK_90 are supplied to the interpolator 30 in differential form: The signal CK_0 consists of differential signal components CK_0_P and CK_0_N. The signal CK_90 consists of differential signal components CK_90_P and CK_90_N. The adjustment of the desired phase shift takes place by means of the signal PHI<2:0>. This is the signal transferred in FIG. 2 from the modulo-8 integrator 40 to the control input of the phase interpolator 30.

FIG. 7 shows finally the (identical) structure of the two interpolator halves 70-1 and 70-2 represented in FIG. 6. The structure of each interpolator half follows a design concept known per se, and comprises a digital-to-analogue converter 74 which converts the signal supplied PHI<2:0>into an analogue representation of the current (symbolised by the represented current sources). The currents supplied from the current sources serve as adjusting currents for respective transconductance stages, each of which as represented is formed from transistor pairs and effects a weighted superposition of the individual currents. The currents are fed via a common resistance load R, so that the potentials PH_OUTP und PH_OUTN indicated in FIG. 6 are provided as voltage drops across the resistance load R. The phase interpolator output signal corresponds to the weighted sum (formed by current superposition) of the CK1 and CK2 input signals, which always possess a phase difference of 90°. The resolution of the phase interpolator output signal is specified as 50 ps.

The frequency and time values given for the above described example of embodiment are, needless to say, only to be understood as examples, and can be modified in practice and adapted to the application concerned.

1. A phase locked loop (12) with a controllable oscillator (DCO) for the generation of an output signal (CKout) of the phase locked loop, and with a phase detector (PD) to determine a phase difference between a clock signal (CKin) used as an input clock signal of the phase locked loop, and the output signal (CKout) of the phase locked loop, and for the provision of a phase detector output signal (PD_OUT) synchronising the oscillator (DCO) with the clock signal (CKin) used,
characterised in that the phase detector (PD) has an adjustable phase shifting device (30) for the generation of an adjusted phase-shifted version (CK<1:8>) of the output signal (CKout) of the phase locked loop, and a phase comparison device (32) generating the phase detector output signal (PD_OUT) to determine the phase difference between the clock signal (CKin) used and the adjusted phase-shifted version (CK<1:8>) of the output signal (CKout), and in that the adjusted phase-shifted version (CK<1:8>) of the output signal of (CKout) is provided as a further output signal (CK<1>) of the phase locked loop.

2. The phase locked loop according to claim 1, wherein the oscillator (DCO) is designed such that the output signal (CKout) is to be provided with a plurality of phases (CK_0, CK_90) for the phase detector (PD), and the adjustable phase shifting device (30) is designed as an adjustable phase interpolator for the interpolation between these phases (CK_0, CK 90) and for the provision of an adjusted interpolated signal (CK<1:8>).

3. The phase locked loop according to claim 2, wherein
the interpolated signal (CK<1:8>) is provided with a plurality of phases (CK<1>, CK<2>, CK<3>. . . ) and one of these phases (CK<1>) is provided as the further output signal of the phase locked loop.

4. The phase locked loop according to claim 1, wherein
the phase detector output signal (PD_OUT) is a digital representation of the phase difference determined.

5. The phase locked loop according to claim 1, comprising a switching device (22) for the switch between a first clock signal (CKin1) and a second clock signal (CKin2) to be used as an input clock signal (CKin) of the phase locked loop, wherein for each of the two clock signals (CKin1, CKin2) a separate phase detector (PD1, PD2) is provided that is connected with the switching device (22).

6. The phase locked loop according to claim 5, wherein
each of the phase detectors (PD1 or PD2) can be switched between a first operating mode for the clock signal currently being used (CKin1 or CKin2) and a second operating mode for the clock signal currently not being used (CKin2 or CKin1), and wherein
the phase shifting device (30) of the phase detector currently in the second operating mode (PD2 or PD1) is adjusted to avoid a phase jump during the switch.

7. The phase locked loop according to claim 6, wherein
each phase detector (PD) contains a phase locked loop (36, 38, 40) activated in the second operating mode, which controls the phase detector output signal (PD_OUT) representing the phase difference such that this phase detector output signal (PD_OUT) is used for an adjustment of the phase shifting device (30).

8. A phase locked loop circuit (10), comprising a phase locked loop (12) according to claim 1, and an output switching device (13-1 to 13-4) connected with a plurality of circuit outputs, to which the output signal (CKout) of the phase locked loop (12) and the further PLL output signal (CK<1>) are supplied, and which forwards to the plurality of circuit outputs in each case either the output signal (CKout) or the further output signal (CK<1>).

9. A method for the operation of a phase locked loop (12), in which with a controllable oscillator (DCO) an output signal (CKout) of the phase locked loop is generated, and with a phase detector (PD) a phase difference is determined between a clock signal (CKin) used as an input clock signal of the phase locked loop, and the output signal (CKout) of the phase locked loop, and a phase detector output signal (PD_OUT) is provided synchronising the oscillator (DCO) with the clock signal (CKin) used,
characterised in that for the determination of the phase difference an adjusted phase-shifted version (CK<1:8>) of the output signal (CKout) of the phase locked loop is generated and compared with the phase of the clock signal being used (CKin), and in that the adjusted phase-shifted version (CK<1:8>) of the output signal (CKout) is provided as a further output signal (CK<1>) of the phase locked loop.
